(19) United States
(12) Patent Application Publication
(10) Pub. No.: US 2009/0166820 A1
(43) Pub. Date: Jul. 2, 2009

(54) TSOP LEADFRAME STRIP OF MULTIPLY ENCAPSULATED PACKAGES

(76) Inventors: Hem Takiar, Fremont, CA (US); Shrikar Bhagath, San Jose, CA (US); Ming Hsun Lee, Taichung (TW); Bonnie Ming-Yan Chan, Sunnyvale, CA (US)

Correspondence Address: VIERRA MAGEN/SANDISK CORPORATION, 575 MARKET STREET, SUITE 2500, SAN FRANCISCO, CA, 94105, US

(21) Appl. No.: 11/965,709

(22) Filed: Dec. 27, 2007

(51) Int. Cl. H01L 23/495; H01L 21/56

(52) U.S. Cl. 257/666; 438/112; 257/E23.031; 257/E21.502

(57) ABSTRACT

A method of fabricating a semiconductor leadframe package from a strip including multiply encapsulated leadframe packages, and a leadframe package formed thereby are disclosed. An entire row or column of leadframes gets encapsulated together. Encapsulating an entire row or column reduces the keep-out area between adjacent leadframe packages, which allows the internal leads of each leadframe and the semiconductor die coupled thereto to be lengthened.

### BACKGROUND OF THE INVENTION

1. Field of the Invention

Embodiments of the present invention relate to a method of fabricating a semiconductor package, and a semiconductor package formed thereby.

2. Description of the Related Art

As the size of electronic devices continue to decrease, the associated semiconductor packages that operate them are being designed with smaller form factors, lower power requirements and higher functionality. Currently, sub-micron features in semiconductor fabrication are placing higher demands on package technology including higher lead counts, reduced lead pitch, minimum footprint area and significant overall volume reduction.

One branch of semiconductor packaging involves the use of a leadframe, which is a thin layer of metal on which one or more semiconductor die are mounted. The leadframe includes electrical leads for communicating electrical signals from the one or more semiconductors to a printed circuit board or other external electrical devices. Common leadframe-based packages include plastic small outlined packages (PSOP), thin small outlined packages (TSOP), and shrink small outline packages (SSOP).

Typically, leadframe packages are fabricated on a strip such as strip 20 shown in prior art FIG. 1. Strip 20 includes a 2×8 matrix of leadframe packages 22 though strips having different numbers of rows and/or columns of packages 22 are known. Prior art FIG. 2 is an enlarged view of a pair of leadframe packages 22 during fabrication on strip 20. Each leadframe package 22 includes a leadframe 24 having a pattern of internal leads 26 coupled to external leads 28. As seen in FIG. 1, external leads 28 extend outside of the leadframe package 22 and are used to electrically couple package 22 to a printed circuit board on which the package 22 is mounted. Standard TSOP packages come in 32-lead, 40-lead, 48-lead and 56-lead packages (fewer external leads are shown in the Figures for clarity). Semiconductor die 30 (shown in dash lines in prior art FIG. 2) may be mounted on the leads or to a die attach pad (not shown) on leadframe 24. The die 30 may be electrically coupled to internal leads 26 via wire bonds between internal leads 26 and die bond pads on the surface of the semiconductor die.

After the die have been mounted and all electrical connections have been established, the respective leadframe packages are encapsulated in a molding compound 32 as shown in FIG. 1 and as explained in greater detail with respect to prior art FIGS. 3-5. FIG. 3 is a cross-sectional view through line 3-3 in FIG. 1 showing a pair of encapsulated leadframe packages 22 on strip 20 encapsulated in molding compound 32. As seen in the cross-sectional view of FIG. 4 and the perspective view of FIG. 5, in order to encapsulate the leadframe packages 22 on strip 20, the strip 20 is positioned within a tool between upper and lower mold plates 40 and 42. In conventional encapsulation processes, each leadframe package is individually encapsulated. Accordingly, both the upper and lower mold plates 40 and 42 include individual recesses 46 (only those in upper plate 40 being visible in FIG. 5).

The strip is positioned between the upper and lower mold plates so that the recesses 46 align over each of the respective leadframe packages 22 on the strip 20. Once the strip 20 is properly positioned between the mold plates, the mold plates are closed against the strip 20 and a mold compound, for example molten epoxy resin, is then injected into each of the cavities defined by the upper and lower mold plates to encapsulate each of the leadframe packages on strip 20 as shown in FIGS. 1, 3 and 4.

As each leadframe package is encapsulated around all four sides, the leadframe packages must be laid out on strip 20 with adequate spacing between each package. In particular, across the width of the strip 20, a keep-out area 50 (FIGS. 1 and 3) must be provided to allow the individual encapsulation of each leadframe package across the width of the strip. While the distance across the width between encapsulated packages may be made small, a relatively large keep-out area 50 must nonetheless be provided between adjacent leadframes 22 laid out on strip 20 to ensure that each leadframe is completely encapsulated within the mold compound. This large keep-out area 50 is unused space and reduces the yield of fabricated leadframe packages from a given strip 20.

### SUMMARY OF THE INVENTION

The present invention, roughly described, relates to a method of fabricating a semiconductor leadframe package from a strip including multiply encapsulated leadframe packages, and a leadframe package formed thereby. In embodiments, instead of individually encapsulating each leadframe on the strip, an entire row or column of leadframes is encapsulated. Encapsulating an entire row or column reduces the keep-out area between adjacent leadframe packages. A reduction in the keep-out area allows the internal leads of each leadframe to be lengthened, and consequently the size of the semiconductor die affixed to the leadframe may be increased. Alternatively, the length of the internal leads and size of the semiconductor die may be kept as in prior art leadframes, but the reduction in the keep-out area may allow the addition of an extra row or column of leadframe packages on the strip.

After the rows or columns of leadframe packages are encapsulated on the strip, the individual leadframe packages may be singulated from the strip. In embodiments where for example a column of leadframe packages have been encapsulated, the strip may be cut with a saw blade across each of the columns on a strip. In addition to separating each of the leadframes in a given column, the saw cuts through a tie bar previously supporting the internal leads on each leadframe to thereby electrically isolate each of the internal leads on the leadframe. Thereafter, each leadframe in the rows of leadframes may be singulated from each other as by a stamping process or a further cutting process.

### BRIEF DESCRIPTION OF THE DRAWINGS

FIG. 1 is a top view of a prior art strip of encapsulated leadframe packages.

FIG. 2 is an enlarged top view of a pair of prior art leadframes during the fabrication process prior to encapsulation.

FIG. 3 is a prior art cross-sectional view through line 3-3 of FIG. 1.

FIG. 4 is a cross-sectional view showing the prior art leadframe packages of FIG. 3 between a pair of mold plates.

FIG. 5 is a perspective view of a prior art leadframe strip between a pair of prior art mold plates.

FIG. 6 is a top view of a leadframe strip according to an embodiment of the present invention including multiply encapsulated leadframe packages.

FIG. 7 is a cross-sectional view through line 7-7 of FIG. 6.

FIG. 8 is a flowchart of a process for fabricating leadframes according to embodiments of the present invention.

FIG. 9 is an enlarged top view of a pair of leadframes during fabrication prior to affixation of semiconductor die to the leadframe.

FIG. 10 is an enlarged top view of a pair of leadframes during fabrication prior to encapsulation.

FIG. 11 is a perspective view of a leadframe strip between a pair of mold plates for molding the strip according to embodiments of the present invention.

FIG. 12 is a cross-sectional view of a leadframe strip as shown in FIG. 7 between a pair of mold plates for molding the strip according to embodiments of the present invention.

FIG. 13 is a top view of a pair of leadframe packages during fabrication prior to singulation of the packages.

FIG. 14 is a side view of a finished leadframe package according to embodiments of the present invention.

FIG. 15 is an end view of a finished leadframe package according to embodiments of the present invention.

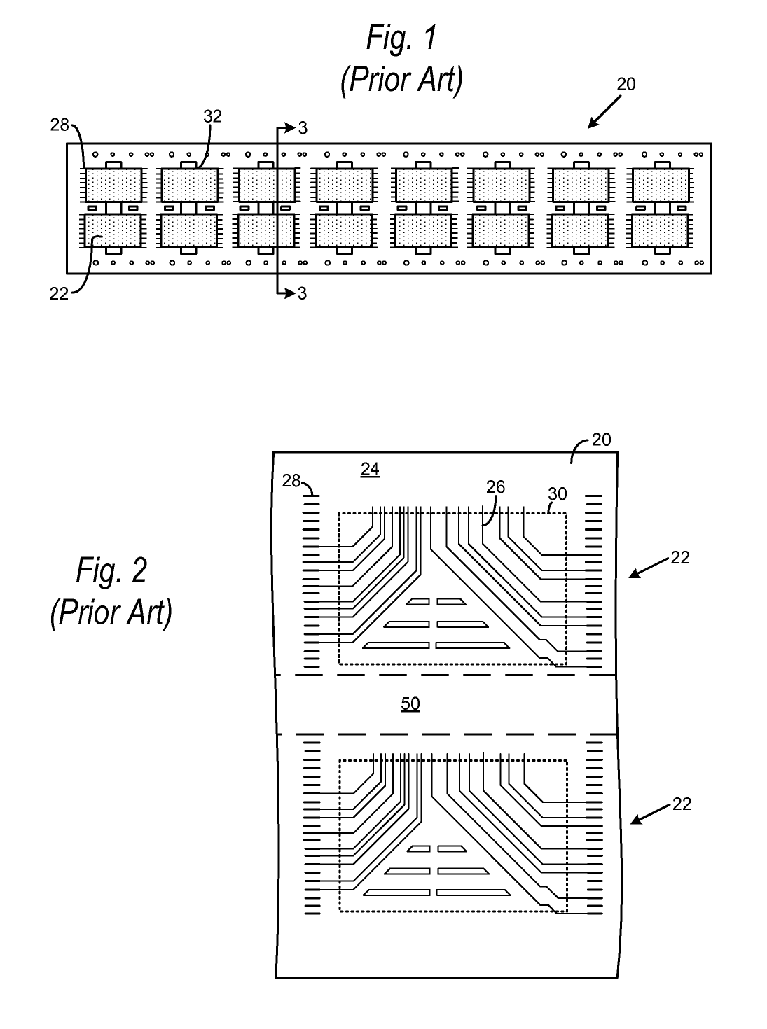

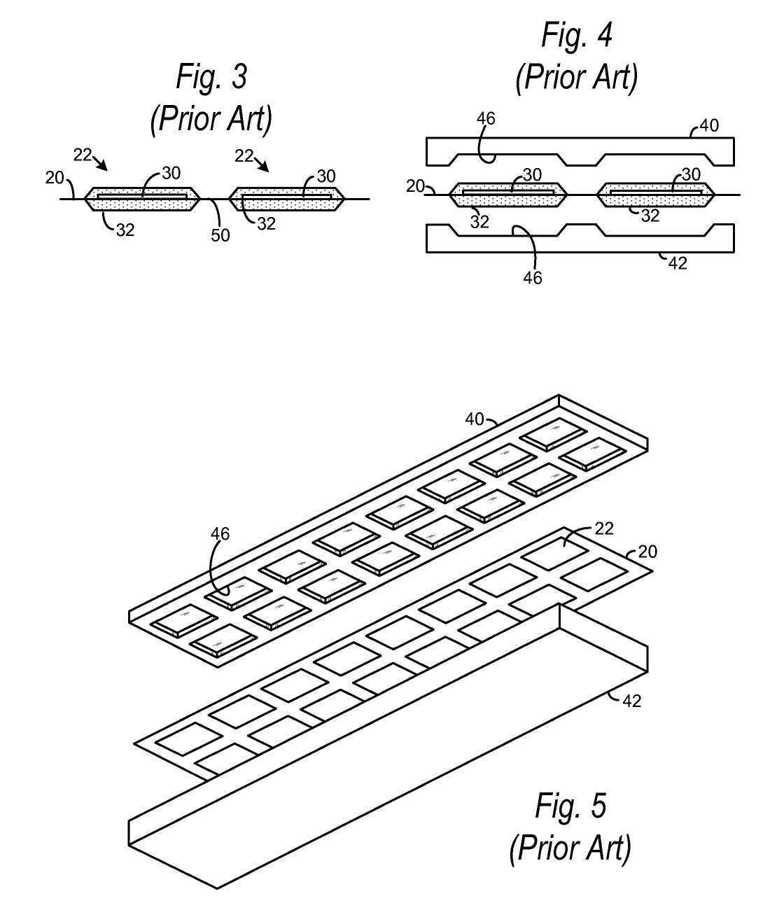

### DETAILED DESCRIPTION

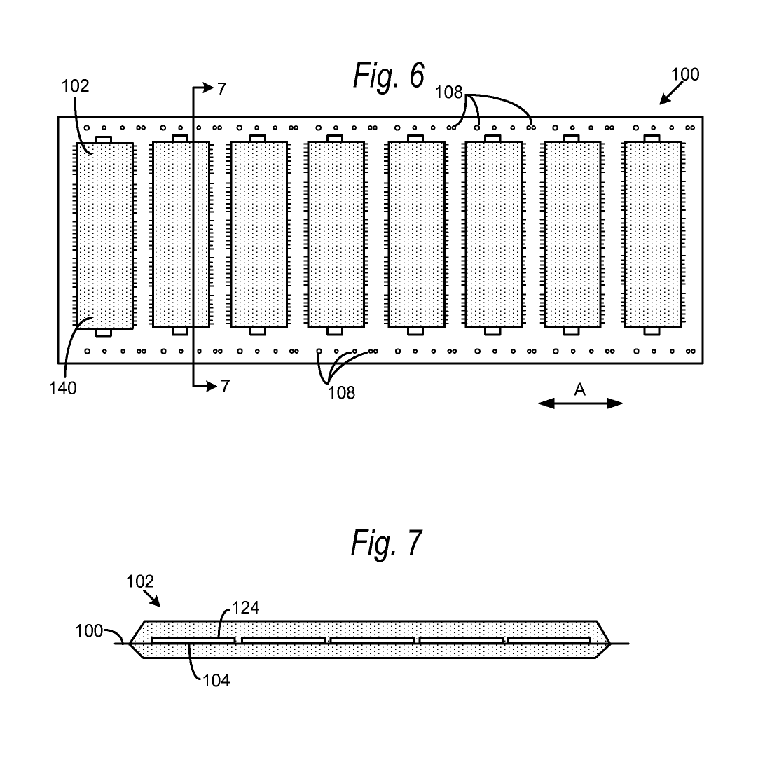

Embodiments of the present invention will now be described in reference to FIGS. 6-15 which in general relate to methods of fabricating a leadframe semiconductor package and a leadframe semiconductor package formed thereby. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

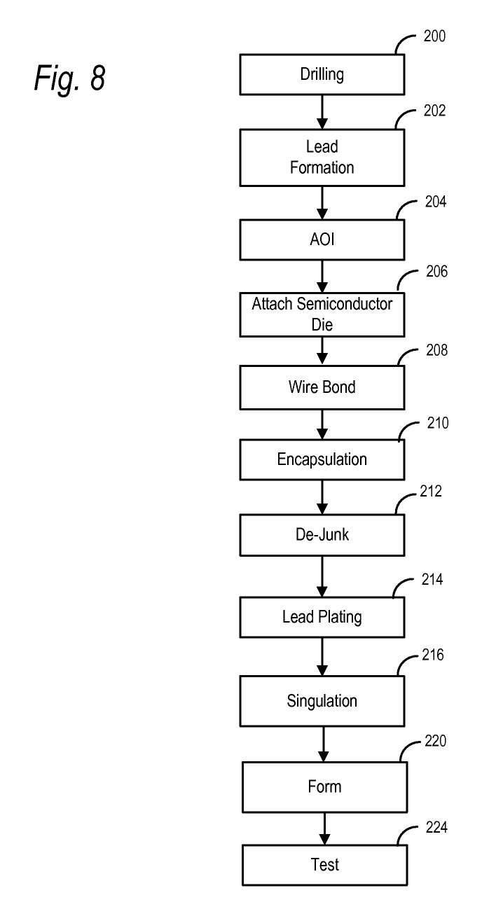

Details relating to the fabrication of a semiconductor leadframe package according to the present invention will be described in detail hereinafter with respect to the flowchart of FIG. 8. However, aspects of the present invention are introduced with respect to the top view of FIG. 6 and the cross-sectional view of FIG. 7. FIG. 6 shows a leadframe strip 100 including multiply encapsulated columns 102 of leadframe packages. FIG. 7 is a cross-sectional view through line 7-7 of FIG. 6. As seen in FIG. 7, each column 102 of leadframe packages includes five leadframes 104. It is understood that the number of leadframes 104 within an encapsulated column 102 may be more or less than five in alternative embodiments of the present invention. Moreover, strip 100 shows eight columns 102 of encapsulated leadframes 104. It is understood that strip 100 may include more or less than eight columns in alternative embodiments of the present invention. Moreover, as described hereinafter, instead of encapsulating columns of leadframes on strip 100, leadframe packages may be assembled on strip 100 so that rows of leadframes 104 are encapsulated.

Encapsulating an entire row or column of leadframes together allows for the reduction in the size of the keep-out area between adjacent leadframes. A reduction in the keep-out area allows the internal leads of each leadframe to be lengthened, and consequently the size of the semiconductor die affixed to the leadframe may be increased.

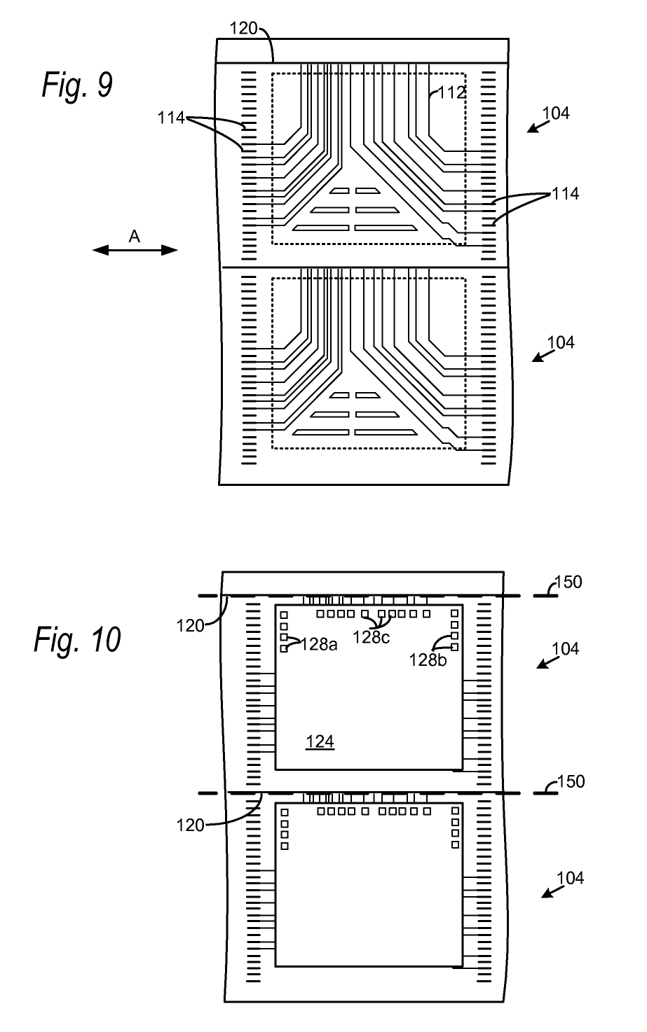

The fabrication of leadframe packages on strip 100 will now be described with reference to the flowchart of FIG. 8. In step 200, a number of fiducial holes 108 are formed though strip 100. Fiducial holes 108 are used by optical sensors to position strip 100 in the various process tools used to form leadframe packages on strip 100. In step 202, the leads are formed on each leadframe 104 on strip 100. A pair of leadframes 104 from a column of leadframes on strip 100 are shown in FIG. 9. It is understood that each of the leadframes 104 on strip 100 may be formed with the same internal and external lead structure as described hereinafter.

Leadframes 104 each include internal leads 112 and external leads 114. Internal leads 112 are provided to transfer signals between the bond pads of semiconductor die (described hereinafter) and the external leads 114. External leads 114 in turn transfer signals from the internal leads to a printed circuit board or host device to which the finished leadframe package is mounted. Embodiments of the present invention operate with leadframes including external leads 114 on a single side of the leadframe 104, or on two opposed sides of the leadframe 104 as shown in FIG. 9. As used herein, the term “pin-out direction” refers to the direction along the length or width of strip 100 which is parallel to the orientation of external leads 114 on strip 100. Thus, the pin-out direction in FIGS. 6 and 9 is oriented in the direction of arrow A, i.e., along the length of the strip 100.

Some internal leads (not shown) are located adjacent external leads 114 and extend only a short distance inward for connecting with die bond pads located on a side of the semiconductor die adjacent the external leads 114. However, owing to the large number of electrical connections required between the semiconductor die and leadframe 104, typically the semiconductor die will include die bond pads along a greater number of sides than simply the sides of the die adjacent external leads 114. Therefore, internal leads 112 are provided to connect the die bond pads on the semiconductor die to the external leads 114 from sides of the die that are spaced from leads 114. In accordance with aspects of the present invention, the internal leads 112 shown in the Figures may be lengthened relative to those in conventional leadframes as described in greater detail hereinafter.

Leadframe 104 may further include tie bar 120 on each leadframe. During fabrication, the ends of the internal leads 112 may be affixed to tie bar 120 so that tie bar 120 structurally supports the internal leads 112 during leadframe fabrication. It is understood that the particular layout of internal leads 112, external leads 114 and tie bar 120 shown in the Figures is by way of example, and the actual number and/or position of internal leads 112, external leads 114 and tie bars 120 may vary in alternative embodiments of the present invention. Internal leads 112, external leads 114 and tie bars 120 may be formed on leadframes 104 by known processes such as for example mechanical stamping or various photolithographic processes.

After the pattern of leads has been defined on the strip 100, the leadframes 104 on strip 100 may be inspected in an automatic optical inspection (AOI) in a step 204. Once inspected, one or more semiconductor dies 124 may be affixed to leadframe 104 in step 206 and as shown in FIG. 10 (and in phantom in FIG. 9). Semiconductor die 124 may for example be one or more flash memory chips (NOR/NAND), though other types of memory die are contemplated. While FIG. 10 shows a single die, it is understood that multiple dies may be included. In addition to one or more memory chips, a controller die, such as for example an ASIC, may also be included.

Semiconductor die 124 is mounted on leadframe 104 so that internal leads 112 shown in the Figures extend beneath the semiconductor die and have ends extending out beyond a top edge of the semiconductor die. Die bond pads along the top edge of die 124 (from the perspective of FIG. 9) may be wire bonded to the exposed portions of internal leads 112 as described hereinafter. In FIGS. 9 and 10, semiconductor die 124 is shown mounted directly to leads 112 in a chip-on-lead (COL) configuration. In alternative embodiments, a die paddle may be included on leadframe 104 for supporting semiconductor die 124 as is known in the art.

As indicated above, semiconductor die 124 may include a set of die bond pads 128 around different edges of the semiconductor die. For example, die bond pads 128a lie adjacent external leads 114 on a first side of the die. Die bond pads 128b lie adjacent external leads 114 on the opposite side of the die, and die bond pads 128c lie adjacent a top edge of the semiconductor die spaced from the external leads 114. It is understood that many more die bond pads 128 may be included on die 124 than is shown in FIG. 10. As indicated above, die bond pads 128c lie adjacent to ends of internal leads 112 which may extend below the semiconductor die to connect with external leads 114.

In step 208, semiconductor die 124 may be electrically coupled to leadframe 104 in a known wire bond process. In particular, die bond pads 128a and 128b may be wire bonded to internal leads (not shown) extending between die bond pads 128a/128b and external leads 114. The die bond pads 128c may be wire bonded to ends of the shown internal leads 112, for example at a top of the leadframe 104.

While semiconductor die 124 is shown mounted on top of internal leads 112, it is understood that semiconductor die 124 may be mounted beneath leadframe 104 with a surface including die bond pads mounted directly to the internal leads, or with semiconductor die 124 flipped over so that a surface not including die bond pads 128 are mounted directly to a bottom surface of the internal leads 112. The die mounted on the top surface of the leadframe 104 is not down-set. However, the leadframe 104 may include a down-set in alternative embodiments.

Owing to the fact that a number of leadframes 104 are encapsulated together as explained in greater detail below, the keep-out area between adjacent semiconductor die in a direction transverse to the pin-out direction may be largely or completely removed. The space formerly reserved as a keep-out area may now be used to increase the length of the internal leads 112, and consequently allows for larger semiconductor die 124 than would otherwise be possible in leadframes of the prior art. As indicated above, the ends of internal leads 112 must extend out beyond the edge of the semiconductor die to allow the connection of wire bonds thereto. The multiple encapsulation of leadframes 104 allows internal leads to be made longer and to extend into the keep-out area otherwise found in prior art leadframes. These longer internal leads allow the semiconductor die 124 to be made larger while still being able to bond to the ends of the internal leads protruding out from beneath the semiconductor die 124.

In embodiments, the multiple encapsulation of leadframes allows the internal leads and the semiconductor die to be lengthened between 0.2 to 0.5 millimeters, and more particularly about 0.4 millimeters. Thus, for example, where prior art leadframes could accommodate a semiconductor die having a width as large as approximately 11.15 millimeters, a leadframe according to the embodiments of the present invention can accommodate a die having a width of approximately 11.55 millimeters. This additional area of semiconductor die 124 can be used to add valuable storage capacity and/or function to the finished leadframe package according to the present invention.

In an alternative embodiment, the internal leads and semiconductor die may be left at the same size as prior art designs, but the additional space gained by using the keep-out area allows the leadframes to be packed more closely together on the strip. This may result in the ability to add an extra row of leadframes on strip 100 extending along the pin-out direction.

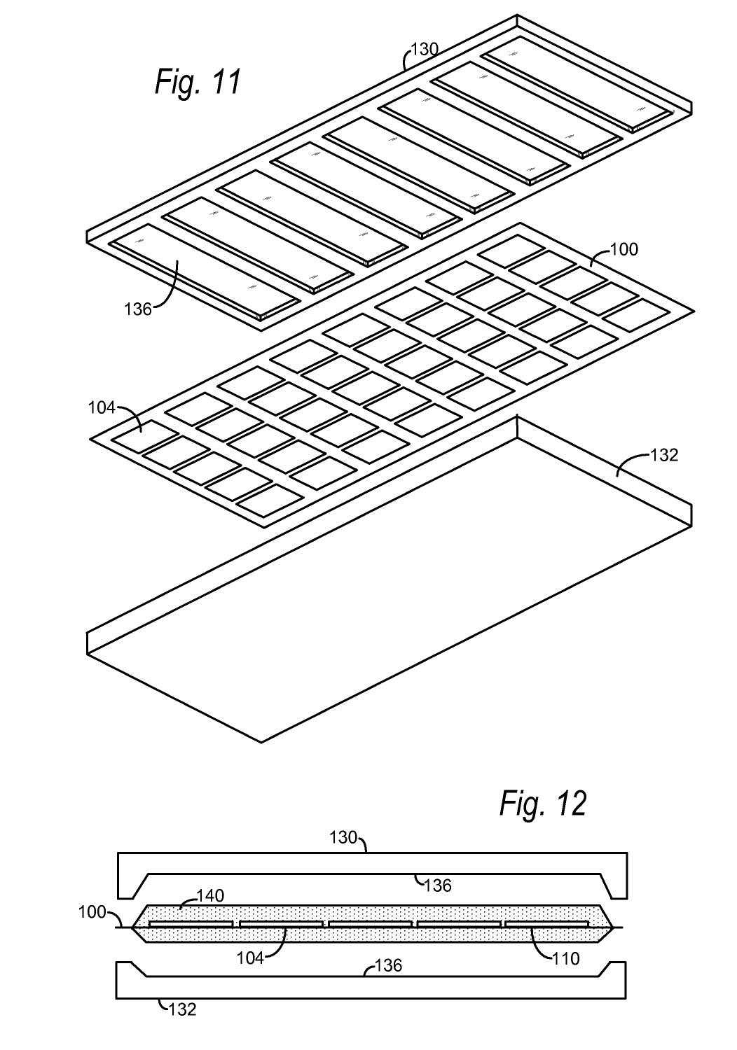

After semiconductor die 124 has been mounted on leadframe 104 and all electrical connections have been established, leadframes may be encapsulated in step 210 as shown in FIGS. 6-7 and as explained with reference to FIGS. 11-13. In order to encapsulate leadframe strip 100, the strip is positioned within a processing tool between an upper mold plate 130 and a lower mold plate 132. As described in the Background of the Invention section, in conventional leadframes, each leadframe package was individually encapsulated. However, in accordance with the present invention, an entire row of leadframes or an entire column of leadframes on strip 100 are encapsulated together.

The leadframes 104 which may be encapsulated together are those which lie transverse to the pin-out direction. In particular, leadframes 104 which lie next to each other along the pin-out direction must be separately encapsulated so that external leads 114 can extend outside of the molding compound. However, packages which lie next to each other transverse to the pin-out direction have no leads which extend outside of the package in that direction and may be encapsulated together. In the embodiments shown in the Figures, the pin-out direction is along the length of strip 100. Accordingly, as shown in FIG. 6, the columns of leadframes transverse to the pin-out direction may be encapsulated together. If, on the other hand, leadframes are oriented so that the pin-out direction was along the width of strip 100 in FIG. 6, respective rows of leadframes 104 on strip 100 could be encapsulated together.

In the embodiment shown in FIG. 6, columns of leadframes are encapsulated together. Accordingly, the upper mold plate 130 and lower mold plate 132 include open recesses 136 which extend the length of an entire column of leadframes. Only the recesses 136 in upper plate 130 are visible in FIG. 11.

In encapsulation step 210, the strip 100 is positioned between the upper and lower mold plates so that the recesses 136 in the top and bottom mold plates align over each column of leadframes 104 on the strip 100. Once the strip 100 is properly positioned between the mold plates, the mold plates are closed against the strip 100 to define cavities around each column of leadframes 104. A mold compound 140 is then injected into each of the cavities defined by the upper and lower mold plates to encapsulate an entire column 102 of leadframes 104 as shown in FIG. 6.

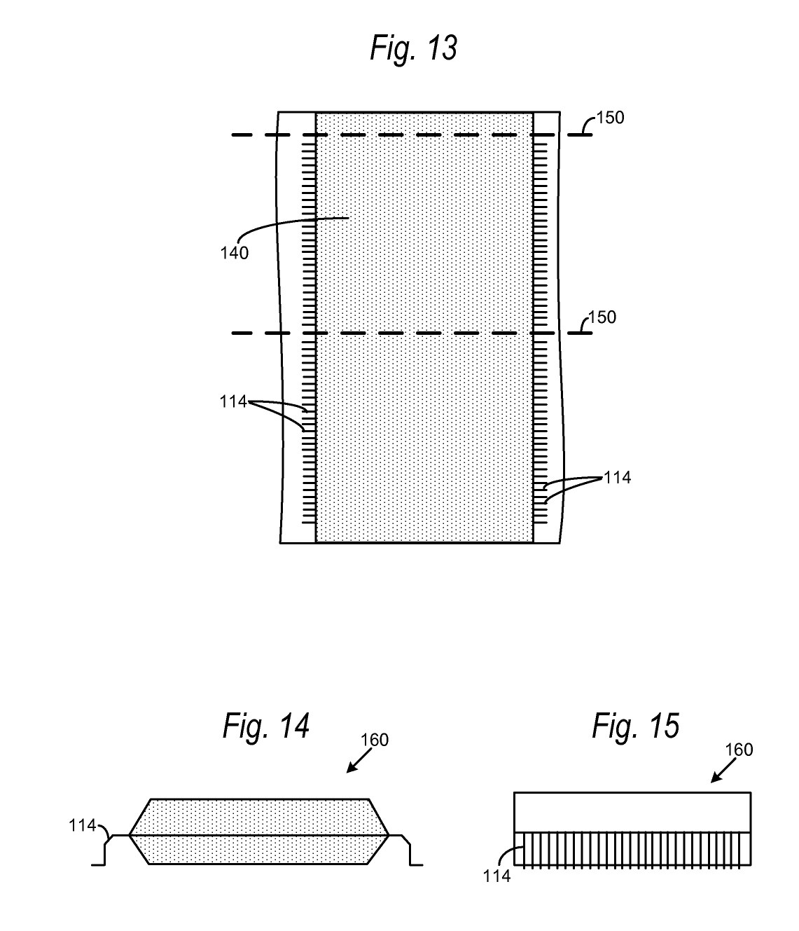

Mold compound 140 may be an epoxy resin such as for example available from Sumitomo Corp. and Nitto Denko Corp., both having headquarters in Japan. Other mold compounds from other manufacturers are contemplated. The mold compound 140 may be applied according to various processes, including by transfer molding or injection molding techniques. The columns of leadframes are encapsulated so that all portions of each leadframe 104 are encapsulated, with the exception of external leads 114 which protrude from the mold compound on each leadframe as seen in FIGS. 6 and 13.

In the embodiments shown in the Figures, the leadframe 104 has the semiconductor die 124 on a top surface of the leadframe and is not down-set. Accordingly, as is known in the art, the recesses 136 formed in the top mold plate 130 may be made deeper than the recesses 136 formed in the bottom mold plate 132. The result is that more mold compound is formed above the leadframe 104 than below it. However, as the one or more die 124 extend above the surface of the leadframe, the amount of mold compound above the semiconductor die 124 is approximately equal to the amount of mold compound below it. In this way, the forces exerted on the semiconductor die 124 from above and below the die during the encapsulation process are at least approximately equal to each other. In alternative embodiments, the leadframe 104 may be down-set. In such embodiments, the recesses in the top and bottom mold plates 130, 132 may have the same depth.

After encapsulation step 210, known “de-junk” step 212 and lead plating step 214 may be performed. The de-junk step separates the external leads 114 and removes excess molding compound 140 due to mold flash. The lead plating step plates portions of external leads 114, for example with tin, to prepare the leads for surface mounting to a printed circuit board or host device (not shown). After steps 212 and 214, individual leadframe packages may be singulated from strip 100 in step 216. Singulation step 216 may include two separate processes. In a first process, a cut may be made along the pin-out direction to cut strip 100 into a plurality of rows, each row including one leadframe from each of the former columns on strip 100.

Referring to FIGS. 11 and 13, this initial cut is made along a cut line 150. The cut along cut line 150 is made through tie bar 120 with a blade that is thick enough to ensure the entire removal of tie bar 120 by the cut. Thus, in addition to separating strip 100 into rows of leadframes, the cut along line 150 removes tie bar 120 and electrically isolates each of the internal leads 112. As indicated above, before being removed, tie bar 120 connected each of the internal leads 112 together. The cut along line 150 may be made using a saw blade, laser, waterjet cutting or any other process which can cut through strip 100 and ensure removal of tie bar 120.

After the cut along the pin-out direction, the second process of singulation step 216 may involve the separation of each of the leadframes in the row of leadframes from each other to provide individual leadframe packages 160 as shown in FIGS. 14 and 15. The second singulation process may be performed by mechanical stamping as known in the art, or may be performed by cutting with a blade, laser, waterjet, etc. The singulation step may further include a known trim step for trimming eternal leads 114 to their proper length.

FIGS. 14 and 15 show side and end views, respectively, of a completed leadframe package 160. After singulation step 216, the external leads are formed in step 220, for example in a gull wing shape as is known in the art to allow surface mounting of the leadframe package 160 to a printed circuit board or host device for exchange of information to and from leadframe package 160. Leadframe package 160 may be tested in step 224 to ensure that package 160 is functioning properly. As is known in the art, such testing may include electrical testing, burn in and other tests. Leadframe packages 160 may for example be a TSOP 48-pin multi-die package. It is understood however that the number of pins and the type of leadframe package may vary in alternative embodiments of the present invention.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A method of fabricating a semiconductor leadframe package, comprising the steps of:
(a) defining a plurality of leadframes on a strip;
(b) mounting one or more semiconductor die on each of the leadframes defined in said step (a);
(c) encapsulating one of entire rows or columns of leadframes together on the strip; and
(d) singulating the encapsulated leadframe packages from the strip.

2. A method as recited in claim 1, wherein said step (a) of defining a plurality of leadframes on a strip comprises the step of defining a plurality of internal leads and external leads.

3. A method as recited in claim 1, wherein said step (a) of defining a plurality of leadframes on a strip comprises the step of defining forty leadframes on the strip in a 5×8 matrix.

4. A method as recited in claim 1, wherein said step (a) of defining a plurality of leadframes on a strip comprises the step of defining leadframes including external leads which extend from two opposite sides of the leadframe in an external lead pin-out direction along one of the rows or columns on the leadframe.

5. A method as recited in claim 4, wherein said step (c) of encapsulating one of entire rows or columns of leadframes together on the strip comprises the step of encapsulating the one of the rows or columns on the leadframe that extend transverse to the pin-out direction.

6. A method as recited in claim 4, wherein the external leads extend in a pin-out orientation along the rows on the strip and the columns on the strip are encapsulated.

7. A method as recited in claim 4, wherein the external leads extend in a pin-out orientation along the columns on the strip and the rows on the strip are encapsulated.

8. A method as recited in claim 1, wherein said step (a) of defining a plurality of leadframes on a strip comprises the step of defining leadframes including external leads which extend from one side of the leadframe in an external lead pin-out direction along one of the rows or columns on the leadframe.

9. A method as recited in claim 8, wherein said step (c) of encapsulating one of entire rows or columns of leadframes together on the strip comprises the step of encapsulating the one of the rows or columns on the leadframe that extend transverse to the pin-out direction.

10. A method as recited in claim 1, wherein said step (b) of mounting one or more semiconductor die on the leadframes comprises the step of mounting a flash memory die and a controller die on the leadframe.

11. A method as recited in claim 1, wherein said step (c) of encapsulating one of entire rows or columns of leadframes together on the strip comprises the step of providing an approximately equal amount of molding compound above the one or more semiconductor die as below the one or more semiconductor die.

12. A method as recited in claim 1, wherein said step (d) of singulating the individual encapsulated leadframe packages from the strip comprises cutting the rows or columns of leadframes from the strip, said cut encompassing a plurality of separately encapsulated packages.

13. A method as recited in claim 12, wherein said step (d) of singulating the individual encapsulated leadframe packages from the strip comprises stamping individual leadframe packages from the rows or columns cut from the strip.

14. A method of fabricating a semiconductor leadframe package, comprising the steps of:
(a) defining a plurality of leadframes on a strip, said defining step comprising defining a plurality of internal and external leads, the external leads being oriented in a pin-out direction along the rows or columns of the leadframe;
(b) mounting one or more semiconductor die on each of the leadframes defined in said step (a);
(c) encapsulating all leadframes together in one of:
(c1) the columns of leadframes if the columns on the strip are oriented transverse to the pin-out direction, or
(c2) the rows of leadframes if the rows on the strip are oriented transverse to the pin-out direction; and
(d) singulating the individual encapsulated leadframe packages from the strip.

15. A method as recited in claim 14, wherein said step (a) of defining a plurality of leadframes on a strip comprises the step of defining leadframes including external leads which extend from two opposite sides of the leadframe in an external lead pin-out direction extending along one of the rows or columns on the leadframe.

16. A method as recited in claim 14, wherein said step (b) of mounting one or more semiconductor die on the leadframes comprises the step of mounting a flash memory die and a controller die on the leadframe.

17. A method as recited in claim 14, wherein said step (c) of encapsulating leadframes comprises the step of providing an approximately equal amount of molding compound above the one or more semiconductor die as below the one or more semiconductor die.

18. A method as recited in claim 14, wherein said step (d) of singulating the individual encapsulated leadframe packages from the strip comprises cutting the rows or columns of leadframes from the strip, said cut encompassing a plurality of separately encapsulated packages.

19. A method as recited in claims 8, wherein said step (d) of singulating the individual encapsulated leadframe packages from the strip comprises stamping individual leadframe packages from the rows or columns cut from the strip.

20. A method of fabricating a semiconductor leadframe package, comprising the steps of:
(a) defining a plurality of leadframes on a strip, said defining step comprising defining a plurality of internal and external leads;
(b) mounting one or more semiconductor die on each of the leadframes defined in said step (a);
(c) encapsulating one of entire rows or columns of leadframes together on the strip;
(d) cutting the strip transverse to the encapsulated rows or columns, said cut severing internal leads of the plurality of internal leads from a tie bar;
(e) singulating individual leadframe packages from rows or columns of leadframes cut in said step (d).

21. A method as recited in claim 20, wherein said step (d) of cutting the strip transverse to the encapsulated rows or columns comprises the step of cutting the strip with a saw blade.

22. A method as recited in claim 20, wherein said step (d) of cutting the strip transverse to the encapsulated rows or columns comprises the step of cutting the strip with a laser.

23. A method as recited in claim 20, wherein said step (e) of singulating individual leadframe packages comprises the step of separating the individual leadframe packages by a stamping process.

24. A method as recited in claim 20, wherein said step (e) of singulating individual leadframe packages comprises the step of separating the individual leadframe packages by a sawing process.

25. A method as recited in claim 20, wherein said step (a) of defining a plurality of leadframes on a strip comprises the step of defining leadframes including external leads which extend in an external lead pin-out direction along one of the rows or columns on the leadframe.

26. A method as recited in claim 25, wherein said step (c) of encapsulating one of entire rows or columns of leadframes together on the strip comprises the step of encapsulating the one of the rows or columns on the leadframe that extend transverse to the pin-out direction.

27. A method as recited in claim 25, wherein the external leads extend in a pin-out orientation along the rows on the strip and the columns on the strip are encapsulated.

28. A method as recited in claim 25, wherein the external leads extend in a pin-out orientation along the columns on the strip and the rows on the strip are encapsulated.

29. A method as recited in claim 25, wherein said step (a) of defining a plurality of leadframes on a strip comprises the step of defining leadframes including external leads which extend out from two opposite sides of the leadframe along the pin-out direction.

30. A leadframe package singulated from a strip, the strip comprising:
a plurality of leadframes oriented in a row or column across the strip;
one or more semiconductor die mounted to each leadframe of the plurality of leadframes; and
mold compound encapsulating all of the plurality of leadframes together.

31. A leadframe package as recited in claim 30, the leadframe including internal leads encapsulated within the mold compound and external leads protruding from the mold compound, the external leads extending in a pin-out direction transverse to the row or column including the plurality of leadframes.

32. A leadframe package as recited in claim 31, wherein the internal leads extend to an edge of the molding compound.

33. A leadframe package as recited in claim 31, wherein the external leads extend out of two opposite sides of the mold compound.

34. A leadframe package as recited in claim 31, wherein the external leads extend out of a single side of the mold compound.

35. A leadframe package as recited in claim 30, the leadframe including a tie bar, an end of a group of internal leads being affixed to the tie bar on the strip, the group of internal leads being severed from the tie bar upon singulation of the leadframe package from the strip.

36. A leadframe package as recited in claim 30, the strip including a 5×8 matrix of leadframes, the plurality of leadframes in the row or column equaling 5 leadframes.

37. A leadframe package as recited in claim 30, wherein the plurality of leadframes are in a column in the strip.

38. A leadframe package as recited in claim 30, wherein the plurality of leadframes are in a row in the strip.

39. A leadframe package as recited in claim 30, wherein the one or more semiconductor die comprise one or more memory die and a controller die.

40. A leadframe package as recited in claim 30, wherein the leadframe package is a TSOP.

41. A leadframe package as recited in claim 30, wherein there is an approximately equal amount of molding compound above the one or more semiconductor die as below the one or more semiconductor die.

42. A leadframe package singulated from a strip, the strip comprising:
a plurality of leadframes arranged in a plurality of rows and a plurality of columns on the strip, each leadframe of the plurality of leadframes including internal leads and external leads, the external leads extending in a pin-out direction transverse to one of the plurality of rows or the plurality of columns;
one or more semiconductor die mounted to each leadframe of the plurality of leadframes; and
mold compound encapsulating all leadframes together in the one of the plurality of rows or the plurality of columns extending transverse to the pin-out direction, the internal leads encapsulated within the mold compound and extending to an edge of the mold compound, and the external leads protruding from the mold compound.

43. A leadframe package as recited in claim 42, wherein the external leads extend out of two opposite sides of the mold compound.

44. A leadframe package as recited in claim 42, the leadframe including a tie bar, an end of a group of internal leads being affixed to the tie bar on the strip, the group of internal leads being severed from the tie bar upon singulation of the leadframe package from the strip.

45. A leadframe package as recited in claim 42, wherein the plurality of columns of leadframes are encapsulated together.

46. A leadframe package as recited in claim 42, wherein the plurality of rows of leadframes are encapsulated together.

47. A leadframe package as recited in claim 42, wherein the one or more semiconductor die comprise one or more memory die and a controller die.

48. A leadframe package as recited in claim 42, wherein the leadframe packagee is a TSOP.
